(19) United States
(12) Patent Application Publication
(10) Pub. No.: US 2013/0193456 A1
(43) Pub. Date: Aug. 1, 2013

(54) ORGANIC LIGHT EMITTING DIODE DISPLAY

(71) Applicants: Sung-Soo Lee, Yongin-si (KR); Ok-Keun Song, Yongin-si (KR); Young-Mo Koo, Yongin-si (KR); Se-Il Kim, Yongin-si (KR)

(72) Inventors: Sung-Soo Lee, Yongin-si (KR); Ok-Keun Song, Yongin-si (KR); Young-Mo Koo, Yongin-si (KR); Se-Il Kim, Yongin-si (KR)

(21) Appl. No.: 13/609,806

(22) Filed: Sep. 11, 2012

(30) Foreign Application Priority Data
Feb. 1, 2012 (KR) 10-2012-0010493

(51) Int. Cl. H01L 33/50

(52) U.S. Cl. 257/88; 257/E33.062

(57) ABSTRACT

An organic light emitting diode display includes a substrate, a white pixel and a color pixel, each including an emission area, a non-emission area, a thin film transistor on the substrate, and an organic light emitting element on the substrate and electrically connected to the thin film transistor and configured to emit light at the emission area, a color filter layer between the organic light emitting element of the color pixel and the substrate at the emission area of the color pixel, and an overcoat layer having an overcoat opening corresponding to the emission area of the white pixel, and covering the color filter layer between the organic light emitting element of the color pixel and the color filter layer.

### RELATED APPLICATIONS

This application claims priority to and the benefit of Korean Patent Application No. 10-2012-0010493 filed in the Korean Intellectual Property Office on Feb. 1, 2012, the entire content of which is incorporated herein by reference.

### BACKGROUND

1. Field

The described technology relates generally to an organic light emitting diode (OLED) display.

2. Description of the Related Art

An organic light emitting diode (OLED) display has received much attention as a next-generation display due to its merits, such as wide viewing angle, fast response rate, and relatively less power consumption, as well as a lesser weight and a slimmer size.

The organic light emitting diode (OLED) display uses light generated by an organic light emitting element formed at each pixel to display an image.

A white (W) pixel for controlling an amount of light without a color component is added to the organic light emitting diode (OLED) display in addition to red, green, and blue (RGB) pixels that are generally used to express an image with various colors, so the organic light emitting diode (OLED) display having red, green, blue, and white (RGBW) pixels has gained attention. The organic light emitting diode (OLED) display has a merit of improving color representation capability and luminance.

However, the red, green, and blue (RGB) pixels have a different configuration from that of the white pixel, so when many insulation layers used for the organic light emitting diode (OLED) display are equivalently applied to the red, green, and blue (RGB) pixels as well as the white pixel, optical efficiency of the white pixel is deteriorated.

The above information disclosed in this Background section is only for enhancement of understanding of the background of the described technology and therefore it may contain information that does not form the prior art that is already known in this country to a person of ordinary skill in the art.

### SUMMARY

Embodiments of the present invention provide an organic light emitting diode (OLED) display for efficiently improving an optical characteristic of a white pixel while using a color pixel and the white pixel.

An exemplary embodiment of the present invention provides an organic light emitting diode display including a substrate, a white pixel and a color pixel, each including an emission area, a non-emission area, a thin film transistor on the substrate, and an organic light emitting element on the substrate and electrically connected to the thin film transistor and configured to emit light at the emission area, a color filter layer between the organic light emitting element of the color pixel and the substrate at the emission area of the color pixel, and an overcoat layer having an overcoat opening corresponding to the emission area of the white pixel, and covering the color filter layer between the organic light emitting element of the color pixel and the color filter layer.

The organic light emitting elements may emit light toward the substrate.

The color pixel may correspond to at least one of a plurality of colors.

The color filter layer and the overcoat layer may include an organic material.

The organic light emitting diode display may further include a buffer layer between the substrate and the thin film transistors and having buffer openings corresponding to the emission areas.

The buffer layer may include multiple layers including different materials, and at least one of the multiple layers of the buffer layer may be less than 10 nm thick and include an inorganic material.

Each of the thin film transistors may include an active layer including a semiconductor material, a gate electrode including a conductive material, and a gate insulating layer between the active layer and the gate electrode for insulating the active layer from the gate electrode and having a gate insulating opening corresponding to a corresponding one of the emission areas.

The gate insulating openings and the buffer openings may expose the substrate.

The gate insulating layer and the buffer layer may have a same pattern.

The gate insulating layer may include multiple layers including different materials, and at least one of the multiple layers of the gate insulating layer may be less than 10 nm thick and include an inorganic material.

The organic light emitting diode display may further include a capacitor including a first capacitor electrode at a same layer as the active layer, and a second capacitor electrode at a same layer as the gate electrodes, and the gate insulating layer may be between the first capacitor electrode and the second capacitor electrode as a dielectric material.

The organic light emitting diode display may further include an interlayer insulating layer contacting the substrate in the emission areas and covering the gate electrodes.

The interlayer insulating layer may include multiple layers including different materials, and the multiple layers of the interlayer insulating layer may be greater than 10 nm thick and include an inorganic material.

The organic light emitting diode display may further include an overcoat protective layer between the overcoat layer and the organic light emitting elements, and the overcoat protective layer may be greater than 10 nm thick and include an inorganic material.

The organic light emitting diode display may further include a color filter protective layer between the color filter layer and the interlayer insulating layer, and the color filter protective layer may be greater than 10 nm thick and include an inorganic material.

According to an embodiment of the present invention, the organic light emitting diode (OLED) display efficiently improves the optical characteristic of the white pixel while using the color pixel and the white pixel.

### BRIEF DESCRIPTION OF THE DRAWINGS

FIG. 1 shows a cross-sectional view of a color pixel area of an organic light emitting diode (OLED) display according to an exemplary embodiment of the present invention.

FIG. 2 shows a cross-sectional view of a white pixel area of an organic light emitting diode (OLED) display according to an exemplary embodiment of the present invention.

FIG. 3 and FIG. 4 show graphs for comparing an experimental example and a comparative example according to an exemplary embodiment of the present invention.

### DETAILED DESCRIPTION

Embodiments of the present invention will be described more fully hereinafter with reference to the accompanying drawings, in which exemplary embodiments of the present invention are shown. As those skilled in the art would realize, the described embodiments may be modified in various ways, all without departing from the spirit or scope of the present invention.

The drawings are schematic and not necessarily proportionally scaled. Relative scales and ratios in the drawings may be enlarged or reduced for the purpose of accuracy and/or convenience, and the scales may be random and not limited thereto. In addition, like reference numerals designate like structures, elements, or parts throughout the specification. It will be understood that when an element is referred to as being “on” another element, it can be directly on another element, or intervening elements may be present therebetween.

Exemplary embodiments of the present invention represent ideal exemplary embodiments in detail. As a result, various modifications of diagrams are expected. Accordingly, exemplary embodiments are not limited to specific shapes of shown areas, and for example, also include modifications of the shape by manufacturing.

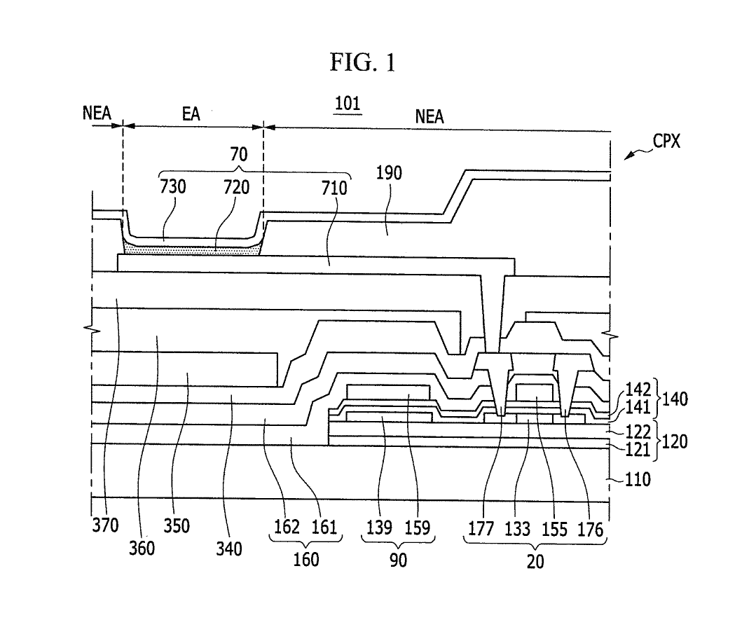

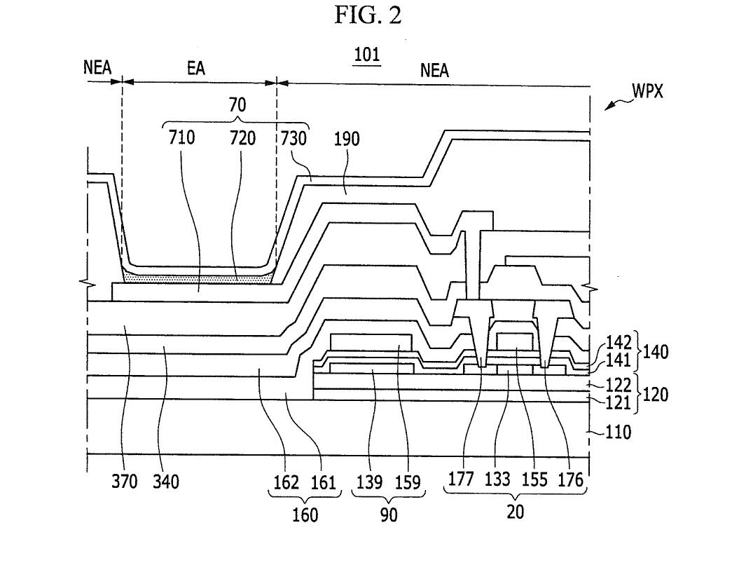

An organic light emitting diode (OLED) display 101 according to an exemplary embodiment will now be described with reference to FIG. 1 and FIG. 2.

As shown in FIG. 1 and FIG. 2, the organic light emitting diode (OLED) display 101 of the present embodiment uses a color pixel (CPX) and a white pixel (WPX) to display an image, wherein FIG. 1 shows a cross-sectional view of a color pixel (CPX) and FIG. 2 shows a cross-sectional view of a white pixel (WPX). The color pixel (CPX) may have a plurality of colors. For example, the color pixel (CPX) includes a red (R) pixel, a green (G) pixel, and a blue (B) pixel.

Also, areas of the respective pixels (CPX, WPX) are classified by emission areas (EA) and non-emission areas (NEA).

The organic light emitting diode (OLED) display 101 will now be described in detail in a stacked order focusing on a thin film transistor 20, an organic light emitting element 70, and a capacitor 90.

A substrate 110 is formed as a transparent insulating substrate made of, for example, glass, quartz, ceramic, or plastic. However, the exemplary embodiment is not limited thereto. Further, when the substrate 110 is made of plastic, it can be formed to be a flexible substrate.

A buffer layer 120 is formed on the substrate 110. The buffer layer 120 has a buffer opening corresponding to an emission area (EA). That is, the buffer layer 120 reveals (e.g., exposes) the substrate 110 in the emission area (EA). Further, the buffer layer 120 can be formed with a single layer or multiple layers. FIG. 1 shows the buffer layer 120 of the present embodiment in a structure of multi-layers 121 and 122 made of different materials. In the present embodiment, at least one of the layers 121 and 122 of the buffer layer 120 is less than 10 nm thick.

The buffer layer 120 can be made of, for example, an inorganic material such as a silicon oxide layer and a silicon nitride layer by using a chemical vapor deposition method or a physical vapor deposition method.

The buffer layer 120 reduces or prevents diffusion or penetration of moisture or impurities generated by the substrate 110, smoothes the surface, and controls a heat transmission speed during a crystallization process for forming an active layer 133. In other embodiments of the present invention, the buffer layer 120 can be omitted depending on the type of substrate 110 and process conditions.

A semiconductor layer pattern including the active layer 133 and a first capacitor electrode 139 is formed on the buffer layer 120. The active layer 133 and the first capacitor electrode 139 are formed when an amorphous silicon layer is formed on the buffer layer 120 and crystallized to form a polysilicon layer and to pattern the same. However, the present exemplary embodiment is not limited thereto. If needed, the first capacitor electrode 139 can be formed with a material that is different from the active layer 133, and/or can be formed on a layer that is different from the active layer 133. For example, the first capacitor electrode 139 can be made of metal.

A gate insulating layer 140 is formed on the active layer 133 and the first capacitor electrode 139. In detail, the gate insulating layer 140 is formed to cover the active layer 133 and the first capacitor electrode 139 on the buffer layer 120.

The gate insulating layer 140 has a gate insulating opening corresponding to the emission area (EA). That is, the gate insulating layer 140 reveals the substrate 110 in the emission area (EA) together with the buffer layer 120. In detail, the gate insulating opening of the gate insulating layer 140 and the buffer opening of the buffer layer 120 reveal the substrate 110. Also, the gate insulating layer 140 and the buffer layer 120 can be formed with the same pattern.

Further, the gate insulating layer 140 of the present embodiment can be formed in a structure of multiple layers 141 and 142 made of different materials, as shown in FIG. 1. At least one of the layers 141 and 142 of the gate insulating layer 140 is less than 10 nm thick.

The gate insulating layer 140 is formed by including at least one of various inorganic materials such as, for example, tetraethyl orthosilicate (TEOS), silicon nitride (SiNx), and silicon oxide (SiO₂), which are known to a skilled person in the art.

A first conductive layer pattern including a gate electrode 155 and a second capacitor electrode 159 is formed on the gate insulating layer 140. Although not shown, the first conductive layer pattern can further include a gate line.

The gate electrode 155 is formed on the active layer 133 so as to be overlapped on a channel area of the active layer 133. The active layer 133 includes a channel area in which an impurity is not doped, and a source area and a drain area, which are disposed on respective sides of the channel area, and in which an impurity is doped. The gate electrode 155 blocks doping of an impurity in the channel area when the impurity is doped to form the source area and the drain area. Also, the impurity can be doped to the first capacitor electrode 139 when the impurity is doped in the source area and the drain area of the active layer 133.

Further, the first conductive layer pattern including the gate electrode 155 and the second capacitor electrode 159 can be formed inclusive of at least one of various metallic materials known to a person skilled in the art, such as, for example, molybdenum (Mo), chromium (Cr), aluminum (Al), silver (Ag), titanium (Ti), tantalum (Ta), and tungsten (W).

The second capacitor electrode 159 is disposed on the first capacitor electrode 139. In this instance, the gate insulating layer 140 between the first capacitor electrode 139 and the second capacitor electrode 159 is a dielectric material. That is, the first capacitor electrode 139, gate insulating layer 140, and the second capacitor electrode 159 form the capacitor 90.

An interlayer insulating layer 160 is formed on first conductive layer patterns (e.g., gate electrode 155 and second capacitor electrode 159).

The interlayer insulating layer 160 contacts the substrate 110 in the emission area (EA) through the gate insulating opening and the buffer insulating opening.

Also, the interlayer insulating layer 160 of embodiments of the present invention can be formed with multiple layers 161 and 162 made of different materials. FIG. 1 shows the interlayer insulating layer 160 in a structure of multiple layers 161 and 162 made of different materials. The layers 161 and 162 of the interlayer insulating layer 160 are greater than 10 nm thick. Also, the interlayer insulating layer 160 can be formed with an inorganic material such as a silicon nitride layer or a silicon oxide layer.

Further, the interlayer insulating layer 160 and the gate insulating layer 140 include a plurality of contact holes for exposing at least a portion of the active layer 133. The contact holes reveal parts of the source area and the drain area of the active layer 133.

A second conductive layer pattern including a source electrode 176 and a drain electrode 177 is formed on the interlayer insulating layer 160. Although not shown, the second conductive layer pattern can further include a data line and a common power line.

The second conductive layer pattern including the source electrode 176 and the drain electrode 177 can be formed inclusive of at least one of various metallic materials known to a skilled person in the art.

The source electrode 176 and the drain electrode 177 contact the source area and the drain area of the active layer 133 through respective ones of the contact holes formed in the interlayer insulating layer 160 and the gate insulating layer 140.

A color filter protective layer 340 is formed on the second conductive layer pattern. The color filter protective layer 340 can be formed with various inorganic materials known to a person skilled in the art. The color filter protective layer 340 of the present embodiment is greater than 10 nm thick.

A color filter layer 350 is formed on the color filter protective layer 340. In detail, the color filter layer 350 is formed in an emission area (EA) of the color pixel (CPX). That is, the color filter layer 350 is not formed in the emission area (EA) or the non-emission area (NEA) of the white pixel (WPX). For example, the color filter layer 350 includes one or more of a red (R) filter layer, a green (G) filter layer, and a blue (B) filter layer.

An overcoat layer 360 for covering the color filter layer 350 and having an overcoat opening corresponding to the emission area (EA) of the white pixel (WPX) is formed on the color filter layer 350. That is, the overcoat layer 360 is formed in the emission area (EA) and the non-emission area (NEA) of the color pixel (CPX). The color filter layer 350 and the overcoat layer 360 can be formed with, for example, an organic material.

An overcoat protective layer 370 is formed on the overcoat layer 360. The overcoat protective layer 370 can be formed with various inorganic materials known to a person skilled in the art. The overcoat protective layer 370 of the present embodiment is greater than 10 nm thick. Also, the overcoat protective layer 370 contacts the color filter protective layer 340 through the overcoat opening of the overcoat layer 360 in the emission area (EA) of the white pixel (WPX).

A first electrode 710 of the organic light emitting element 70 is formed on the overcoat protective layer 370. The first electrode 710 can be an anode. A part of the first electrode 710 is disposed in the emission area (EA), and another part thereof is connected to the drain electrode 177 of the thin film transistor 20 in the non-emission area (NEA). The first electrode 710 can be made of, for example, a transparent conductive material or a semi-transmissive material.

The transparent conductive material can be at least one of, for example, indium tin oxide (ITO), indium zinc oxide (IZO), zinc indium tin oxide (ZITO), gallium indium tin oxide (GITO), indium oxide (In₂O₃), zinc oxide (ZnO), gallium indium zinc oxide (GIZO), gallium zinc oxide (GZO), fluorine tin oxide (FTO), and aluminum-doped zinc oxide (AZO).

The semi-transmissive material of the present embodiment is formed with a film of metal such as magnesium (Mg), calcium (Ca), lithium (Li), zinc (Zn), aluminum (Al), or silver (Ag), or an alloy thereof. Generally, the semi-transmissive material is less than 20 nm thick. Transmittance of light is increased as the semi-transmissive material becomes thinner, and the same is reduced as it becomes thicker.

An organic emission layer 720 of the organic light emitting element 70 is formed on the first electrode 710. The organic emission layer 720 can be formed with, for example, multiple layers including at least one of an emission layer, a hole injection layer (HIL), a hole transport layer (HTL), an electron transport layer (ETL), and an electron injection layer (EIL). The above-noted layers except the emission layer can be omitted if necessary. When the organic emission layer 720 includes the above-noted layers, the hole injection layer (HIL) is disposed on the first electrode 710 that is the hole injection electrode, and then the hole transport layer (HTL), the emission layer, the electron transport layer (ETL), and the electron injection layer (EIL) are sequentially stacked on the first electrode 710.

A second electrode 730 is formed on the organic emission layer 720. The second electrode 730 can be a cathode. The second electrode 730 can be formed with a reflective material. For example, the reflective material can be metal such as magnesium (Mg), calcium (Ca), lithium (Li), zinc (Zn), aluminum (Al), or silver (Ag), or an alloy thereof.

The organic light emitting element 70 emits light in the direction of the substrate 110 to display an image. That is, the organic light emitting diode (OLED) display 101 is a rear surface light emitting type.

Also, the organic light emitting diode (OLED) display 101 can further include a pixel defining film 190 for defining the emission area (EA). The pixel defining film 190 has a pixel opening corresponding to the emission area (EA), and the organic light emitting element 70 emits light in a pixel opening of the pixel defining film 190. The pixel defining film 190 can be formed with, for example, various organic materials or inorganic materials known to a person skilled in the art.

According to the above-described configuration, the organic light emitting diode (OLED) display 101 can efficiently improve the optical characteristic of the white pixel (WPX) while using the color pixel (CPX) and the white pixel (WPX).

In detail, luminous efficiency can be improved by eliminating unnecessary insulation layers 120 and 140 on an optical path through which the light generated by the organic light emitting element 70 goes to the outside, and by reducing or minimizing a number of the disposed insulation layers 160, 340, and 370.

Further, the insulation layers 160, 340, and 370 that are disposed on the optical path are formed to be greater than 10 nm thick, thereby reducing or minimizing generation of resonance while repeatedly passing through the layers with different refractive indexes.

Further, a loss of light by the white pixel (WPX) can be further reduced by placing only the inorganic insulation layers 160, 340, and 370 on the optical path, thereby removing light loss at the organic layer.

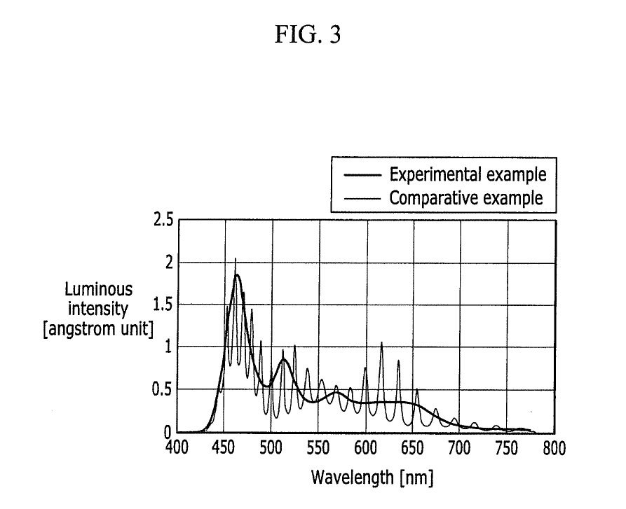

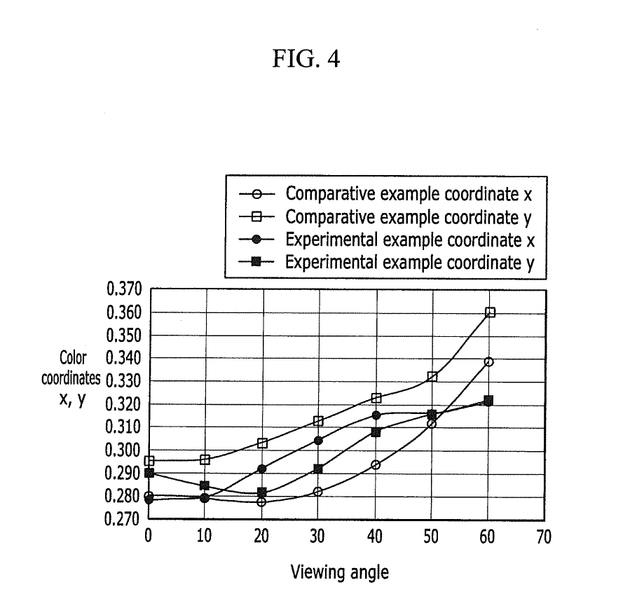

An experimental example according to an exemplary embodiment and a comparative example will now be described with reference to FIG. 3 and FIG. 4.

The experimental example has a structure in which an overcoat layer 360, a gate insulating layer 140, and a buffer layer 120 are removed in the emission area (EA) of the white pixel (WPX).

The comparative example has a structure in which the overcoat layer 360, the gate insulating layer 140, and the buffer layer 120 are disposed in the emission area (EA) of the white pixel (WPX).

As shown in FIG. 3, compared to the comparative example, the experimental example has shown that average intensity of light per wavelength band, that is, transmittance, is improved. Particularly, the comparative example shows a spectrum distribution having many peaks/critical points while the experimental example shows a more stable spectrum distribution.

In addition, as shown in FIG. 4, the experimental example shows relatively fewer changes of the color coordinates x and y with respect to viewing angle compared to the comparative example, so it has excellent optical performance.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims and their equivalents.

What is claimed is:

1. An organic light emitting diode display comprising:
a substrate;
a white pixel and a color pixel, each comprising:
an emission area;
a non-emission area;
a thin film transistor on the substrate; and
an organic light emitting element on the substrate and electrically connected to the thin film transistor and configured to emit light at the emission area;
a color filter layer between the organic light emitting element of the color pixel and the substrate at the emission area of the color pixel; and
an overcoat layer having an overcoat opening corresponding to the emission area of the white pixel, and covering the color filter layer between the organic light emitting element of the color pixel and the color filter layer.

2. The organic light emitting diode display of claim 1, wherein the organic light emitting elements emit light toward the substrate.

3. The organic light emitting diode display of claim 1, wherein the color pixel corresponds to at least one of a plurality of colors.

4. The organic light emitting diode display of claim 1, wherein the color filter layer and the overcoat layer comprise an organic material.

5. The organic light emitting diode display of claim 1, further comprising a buffer layer between the substrate and the thin film transistors and having buffer openings corresponding to the emission areas.

6. The organic light emitting diode display of claim 5, wherein the buffer layer comprises multiple layers comprising different materials, and
wherein at least one of the multiple layers of the buffer layer is less than 10 nm thick and comprises an inorganic material.

7. The organic light emitting diode display of claim 5, wherein each of the thin film transistors comprises:
an active layer comprising a semiconductor material,
a gate electrode comprising a conductive material, and
a gate insulating layer between the active layer and the gate electrode for insulating the active layer from the gate electrode and having a gate insulating opening corresponding to a corresponding one of the emission areas.

8. The organic light emitting diode display of claim 7, wherein the gate insulating openings and the buffer openings expose the substrate.

9. The organic light emitting diode display of claim 7, wherein the gate insulating layer and the buffer layer have a same pattern.

10. The organic light emitting diode display of claim 7, wherein the gate insulating layer comprises multiple layers comprising different materials, and
wherein at least one of the multiple layers of the gate insulating layer is less than 10 nm thick and comprises an inorganic material.

11. The organic light emitting diode display of claim 7, further comprising a capacitor comprising:
a first capacitor electrode at a same layer as the active layer, and
a second capacitor electrode at a same layer as the gate electrodes, wherein the gate insulating layer is between the first capacitor electrode and the second capacitor electrode as a dielectric material.

12. The organic light emitting diode display of claim 7, further comprising an interlayer insulating layer contacting the substrate in the emission areas and covering the gate electrodes.

13. The organic light emitting diode display of claim 12, wherein the interlayer insulating layer comprises multiple layers comprising different materials, and
wherein the multiple layers of the interlayer insulating layer are greater than 10 nm thick and comprise an inorganic material.

14. The organic light emitting diode display of claim 12, further comprising an overcoat protective layer between the overcoat layer and the organic light emitting elements,
wherein the overcoat protective layer is greater than 10 nm thick and comprises an inorganic material.

15. The organic light emitting diode display of claim 12, further comprising a color filter protective layer between the color filter layer and the interlayer insulating layer,
wherein the color filter protective layer is greater than 10 nm thick and comprises an inorganic material.
